(19) United States
(12) Patent Application Publication
(10) Pub. No.: US 2016/0305980 A1
(43) Pub. Date: Oct. 20, 2016

(54) PROBE, SEMICONDUCTOR INSPECTION APPARATUS, METHOD FOR PRODUCING PROBE, METHOD FOR PRODUCING SEMICONDUCTOR INSPECTION APPARATUS, SEMICONDUCTOR INSPECTION METHOD, AND SEMICONDUCTOR PRODUCTION METHOD

(71) Applicant: KABUSHIKI KAISHA TOSHIBA, Tokyo (JP)

(72) Inventor: Toshiaki MISUO, Kawasaki Kanagawa (JP)

(21) Appl. No.: 14/992,608

(22) Filed: Jan. 11, 2016

(30) Foreign Application Priority Data
Apr. 17, 2015 (JP) 2015-085490

(51) Int. Cl. G01R 1/067; G01R 3/00; G01R 1/073

(52) U.S. Cl. CPC G01R 1/06761; G01R 1/07314; G01R 1/06722; G01R 3/00

(57) ABSTRACT

A probe includes a probe pin having a first end and a second end. The first end is connectable to a semiconductor inspection apparatus such as for electrical testing of semiconductor devices. The second end of the probe pin is for contacting an electrode or terminal of the semiconductor device being inspected. The probe pin has at least a portion between first and second ends that is coated with a magnetic substance layer, which can reduce signal noise during inspection. The probe pin is configured to apply a force for maintaining contact between the second end and the electrode when the probe is placed in contact with the first electrode. The force may be generated, for example, by a flexure design of the probe pin or by incorporation of a coil spring.

### CROSS-REFERENCE TO RELATED APPLICATION

This application is based upon and claims the benefit of priority from Japanese Patent Application No. 2015-085490, filed Apr. 17, 2015, the entire contents of which are incorporated herein by reference.

### FIELD

Embodiments described herein relate generally to probes, semiconductor inspection apparatuses, methods for producing probes, methods for producing a semiconductor inspection apparatus, semiconductor inspection methods, and semiconductor production methods.

### BACKGROUND

When the electrical characteristics of a semiconductor device are inspected, a probe in a semiconductor inspection apparatus is connected to an external electrode of the semiconductor device and an electrical signal for inspection is input to the semiconductor device via the probe. At this time, oscillation (noise) of the electrical signal caused by the parasitic or floating capacitance of the semiconductor device and/or the semiconductor inspection apparatus sometimes occurs. As a result of the occurrence of noise, the semiconductor device may be rendered inoperable or a desired inspection result may not be obtained.

### DESCRIPTION OF THE DRAWINGS

FIG. 1 is a block diagram of a semiconductor inspection apparatus according to a first embodiment.

FIG. 2 is a perspective view depicting a probe of the semiconductor inspection apparatus of FIG. 1.

FIG. 3 is a cross sectional view of a probe pin of the probe of the semiconductor inspection apparatus of FIG. 1.

FIG. 4 is an equivalent circuit diagram depicting an example of an inspection device of the semiconductor inspection apparatus of FIG. 1.

FIG. 5A is a schematic waveform diagram obtained by an L load test conducted by using the probe of the first embodiment.

FIG. 5B is a schematic waveform diagram obtained by an L load test conducted by using a probe of a comparative example.

FIG. 6A is a cross sectional view of a probe pin depicting a process of forming the probe pin of the semiconductor inspection apparatus according to the first embodiment.

FIG. 6B is a cross sectional view depicting a process of performing primary coating on a probe pin.

FIG. 6C is a cross sectional view depicting a process of performing magnetic substance thermal spraying on a probe pin.

FIG. 6D is a cross sectional view depicting a process of hardening the magnetic substance on a probe pin.

FIG. 7 is a schematic view of a probe according to a second embodiment.

FIG. 8A is a perspective view of a probe according to a third embodiment.

FIG. 8B is a plan view of a probe according to a third embodiment.

FIG. 9 is a cross sectional view of a probe according to a third embodiment taken on the line IX-IX of FIG. 8A.

### DETAILED DESCRIPTION

An exemplary embodiment provides a probe, a semiconductor inspection apparatus, a method for producing the probe, a method for producing the semiconductor inspection apparatus, a semiconductor inspection method, and a semiconductor production method which may reduce the occurrence of noise when a semiconductor device is inspected by using a probe.

In general, according to one embodiment, a probe includes a first probe pin having a first end and a second end. The first end is connectable to a semiconductor inspection apparatus. The second end is for contacting a first electrode or terminal of a semiconductor device. The first probe pin has at least a portion between its first and second ends that is coated with a magnetic substance layer. The first probe pin is configured to apply a force for maintaining contact between the second end and the first electrode when the probe is placed in contact with the first electrode.

In general, according to another embodiment, a probe includes a probe pin and a magnetic substance layer. The probe pin has a first end and a second end, and is capable of making contact with an electrode of a semiconductor device at the second end. The magnetic substance layer covers the probe pin around the entire perimeter of the probe pin in at least a portion of the probe pin between the first end and the second end.

In general, according to still another embodiment, a method for forming a probe comprises forming a magnetic substance layer on at least one portion of a probe pin of a probe for use in an inspection apparatus, such as, for example, a semiconductor testing apparatus, by performing thermal spraying of a magnetic substance on the probe pin. The portion of the probe pin coated with the magnetic substance layer being between a first and second ends of the probe pin. The first end of the probe pin is connectable to the inspection apparatus and the second end is for making contact with an electrode or terminal of a semiconductor device, such as, for example, a transistor device. The probe pin is configured to apply a force for maintaining contact between the second end and the electrode when the probe is placed in contact with the electrode.

Hereinafter, embodiments will be described with reference to the drawings. The embodiments described below mainly deal with the characteristic configuration and operation of a semiconductor inspection apparatus. However, the semiconductor inspection apparatus may have a configuration and an operation which will be omitted in the following description, and the omitted configuration and operation are also included in the scope of the embodiments.

### First Embodiment

### Semiconductor inspection apparatus 1

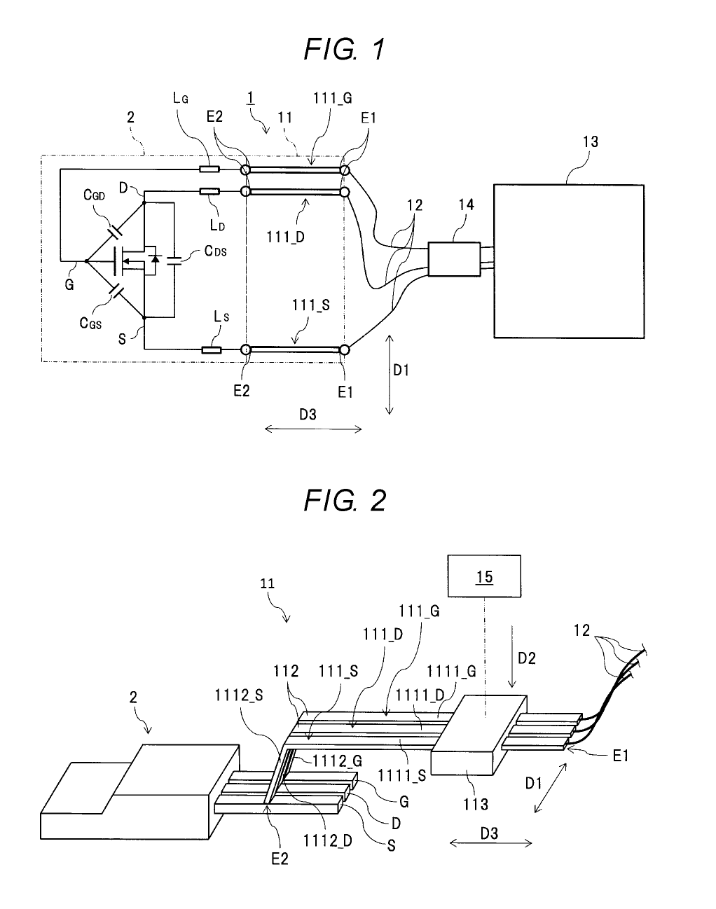

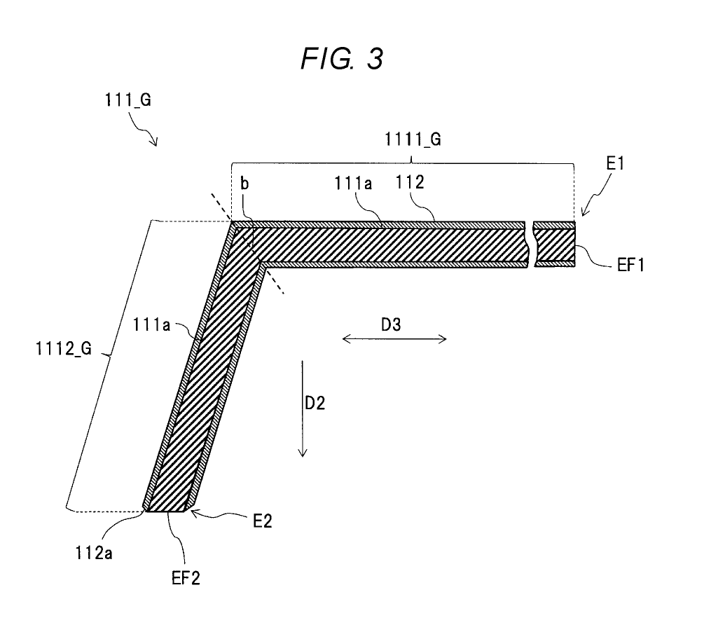

FIG. 1 is a schematic block diagram of a semiconductor inspection apparatus 1 according to the first embodiment. FIG. is a perspective view depicting a probe 11 of the semiconductor inspection apparatus 1. FIG. 3 is a cross sectional view of a probe pin 111 of the probe 11.

The semiconductor inspection apparatus 1 may be used, for example, to inspect the electrical characteristics of a semiconductor device 2 in an inspection process during a manufacturing process for producing the semiconductor device 2 (a semiconductor production method). Incidentally, in FIG. 1, the semiconductor device 2 is a metal oxide semiconductor (MOS) transistor having a conductivity type that is n type, thus semiconductor device 2 maybe referred to in this example as a nMOSFET device. This MOS transistor has three electrodes (terminals): a gate G, a drain D, and a source S. In other examples, the semiconductor device 2 may be a MOS transistor whose conductivity type is a p type (pMOSFET) or a semiconductor device other than a MOS transistor (e.g., bipolar transistor). But for simplicity in explanation, the semiconductor device 2 may be referred to as MOS transistor 2.

As depicted in FIGS. 1 and 2, the semiconductor inspection apparatus 1 includes the probe 11, electric wires 12, an inspection device 13, a ferrite core 14, and a moving apparatus 15 (see FIG. 2). Incidentally, in FIG. 1, the moving apparatus 15 is not specifically depicted. The moving apparatus 15 may, for example, control movement of probe 11 for contacting the semiconductor device 2 being inspected.

As depicted in FIGS. 1 to 3, the probe 11 includes first to third probe pins 111_G, 111_D, and 111_S, a magnetic substance layer 112, and a fixing member 113 (see FIG. 2). The first to third probe pins 111_G, 111_D, and 111_S are arranged with a space between each of the adjacent probe pins in a direction D1. FIG. 1 schematically depicts the first to third probe pins 111_G, 111_D, and 111_S arranged in such away that the first probe pin 111_G and the second probe pin 111_D are narrowly spaced and the second probe pin 111_D and the third probe pin 111_S are widely spaced. These spaces correspond to the spaces between the external electrodes of the MOS transistor 2 (see FIG. 2). Moreover, in FIG. 3, the cross section of the first probe pin 111_G and the magnetic substance layer 112 is depicted as a representative example, but the cross sections of the second and third probe pins 111_D and 111_S are the same as the cross section of the first probe pin 111_G depicted in FIG. 3.

### Probe pins 111_G, 111_D, 111_S

As depicted in FIGS. 1 and 2, each of the probe pins 111_G, 111_D, and 111_S has a first end E1 and a second end E2. As depicted in FIG. 3, an end face EF2 of the second end E2 is substantially flat. The end face EF2 is not covered with the magnetic substance layer 112 and is exposed to the outside. The first probe pin 111_G may make contact with (connect to) the gate G of the MOS transistor 2 at its end face EF2. The second probe pin 111_D may make contact with the drain D of the MOS transistor 2 at its end face EF2. The third probe pin 111_S may make contact with the source S of the MOS transistor 2 at its end face EF2. The probe pins 111_G, 111_D, and 111_S may also be referred to as electrodes or contact electrodes. The second end E2 may also be referred to as a tip or tip end.

As is the case with the end face EF2 on the second end E2, an end face EF1 on the first end E1 of each of the probe pins 111_G, 111_D, and 111_S is also not covered with the magnetic substance layer 112. One end of each of a plurality of electric wires 12 corresponding to the probe pins 111_G, 111_D, and 111_S is connected to the respective end faces EF1 on the first ends E1 of the probe pins 111_G, 111_D, and 111_S. The other end of each electric wire 12 is connected to the inspection device 13.

The probe pins 111_G, 111_D, and 111_S possess elasticity (spring) such that when the probe pins 111_G, 111_D, and 111_S press the second ends E2 against the electrodes G, D, and S, respectively, of the MOS transistor 2 contact between this elements may be improved and/or appropriately maintained. A D2 direction in FIGS. 2 and 3 indicates a pressing direction in which the second ends E2 are pressed against the electrodes G, D, and S of the MOS transistor 2. Pressing of the second ends E2 is implemented as a result of the moving apparatus 15 moving the probe pins 111_G, 111_D, and 111_S in the pressing direction D2.

Moreover, as depicted in FIG. 2, the probe pins 111_G, 111_D, and 111_S respectively have first portions 1111_G, 1111_D, and 1111_S (each including the corresponding first end E1) and second portions 1112_G, 1112_D, and 1112_S (each including the corresponding second end E2). The first portions 1111_G, 1111_D, and 1111_S extend in a direction D3 orthogonal to the direction D1 and the pressing direction D2. The second portions 1112_G, 1112_D, and 1112_S connect to the corresponding first portions 1111_G, 1111_D, and 1111_S at a boundary b between the second portions 1112_G, 1112_D, and 1112_S and the first portions 1111_G, 1111_D, and 1111_S. The boundary b is depicted in FIG. 3 by a dashed line. Furthermore, the second portions 1112_G, 1112_D, and 1112_S are bent towards the pressing direction D2 with respect to the first portions 1111_G, 1111_D, and 1111_S. Specifically, the second portions 1112_G, 1112_D, and 1112_S are at an angle with respect to the pressing direction D2. The size (thickness) of each of the probe pins 111_G, 111_D, and 111_S in the pressing direction D2 may be smaller than the size (width) of each of the probe pins 111_G, 111_D, and 111_S in the arrangement direction D1 so as to make the probe pins 111_G, 111_D, and 111_S easily bendable in the pressing direction D2.

The probe pins 111_G, 111_D, and 111_S are fixed to the fixing member 113 with spaces left therebetween, the spacing corresponding to the spacing between the external electrodes G, D, and S of the MOS transistor 2. Here, the space left between the arranged probe pins 111_G, 111_D, and 111_S is the same as the space left between the arranged electrodes G, D, and S of the MOS transistor 2. The fixing member 113 is formed of an insulating material such as resin to provide insulation between the probe pins 111_G, 111_D, and 111_S.

Since the probe pins 111_G, 111_D, and 111_S may flex in the pressing direction D2, the end faces EF2 of the probe pins 111_G, 111_D, and 111_S may be brought into contact with the electrodes G, D, and S of the MOS transistor 2 with stability. By bringing the end faces EF2 into contact with the electrodes G, D, and S with stability, the MOS transistor 2 may be appropriately inspected with less noise and/or error. Moreover, since the probe pins 111_G, 111_D, and 111_S have the second portions 1112_G, 1112_D, and 1112_S, the probe pins 111_G, 111_D, and 111_S may bring the end faces EF2 into contact with the electrodes G, D, and S of the MOS transistor 2 more stably.

Incidentally, the number of probe pins 111_G, the number of probe pins 111_D, and the number of probe pins 111_S may be one or more than one (for example, two) . That is, the total number of probe pins (111_G, 111_D, and 111_S) can be three or more than three. By providing a plurality of probe pins 111_G, a plurality of probe pins 111_D, and a plurality of probe pins 111_S, the plurality of probe pins (for example, the plurality of first probe pins 111_G) may be brought into contact with one electrode (for example, the gate G) of the MOS transistor 2 at the same time. By bringing the plurality of probe pins into contact with one electrode at the same time, the contact resistance (loss) between the probe pins and the electrode of the MOS transistor 2 may be reduced. Since the contact resistance maybe reduced, heat generation at the probe pins 111_G, 111_D, and 111_S or sparking of the probe pins 111_G, 111_D, and 111_S may be suppressed. Moreover, by bringing a plurality of probe pins into contact with one external electrode, an inspection by Kelvin sensing (a four-terminal method) becomes possible.

### Magnetic Substance Layer 112

The magnetic substance layer 112 reduces noise caused in the MOS transistor 2 when the electrical characteristics of the MOS transistor 2 (the semiconductor device) are inspected. The magnetic substance layer 112 may also be referred to as a magnetic substance coating, a noise absorption layer, or a magnetic substance thermal sprayed film.

As depicted in FIG. 3, the magnetic substance layer 112 covers the probe pins 111_G, 111_D, and 111_S around the entire perimeter thereof in at least a portion of an area of each of the probe pins 111_G, 111_D, and 111_S between the first end E1 and the second end E2. For example, the magnetic substance layer 112 covers the probe pins 111_G, 111_D, and 111_S around the entire perimeter at least a portion of the probe pins 111_G, 111_D, and 111_S between the first end E1 and the second end E2 (that is, the first portions 1111_G, 1111_D, and 1111_S and the second portions 1112_G, 1112_D, and 1112_S).

Moreover, as depicted in FIG. 3, a tip face 112a of the magnetic substance layer 112 on the side where the second end E2 is located includes a portion which is flush with the end face EF2. Furthermore, the tip face 112a of the magnetic substance layer 112 is inclined toward the side where the first end E1 is located as the tip face 112a gets away from an outer periphery 111a of the probe pin 111_G. That is, the tip face 112a is not fully coplanar with the end face EF2, but is rather at angle to the end face EF2 or otherwise at least partially withdrawn from the end face EF2 plane. The tip face 112a may thus be a flat face or a curved face. As a result of the tip face 112a retreating (along the probe pin 111_G longitudinal direction) toward the first ends E1 with respect to the second ends E2, the end faces EF2 may be brought into contact with the electrodes G, D, and S of the MOS transistor 2 more appropriately without substantial or significant contact between the magnetic substance layer 112 and the electrode(s) of the MOS transistor 2. In some embodiments, the tip face 112a need not include the portion which is flush with the end face EF2. That is, the whole portion of the tip face 112a of the magnetic substance layer 112 may be located on the side closer to the first end E1 than the end face EF2—that is, the magnetic layer 112 may be removed from some portion of the probe pin (111_G) adjacent to the second end E2 of the probe pin. The other probe pins (111_D and 111_S) maybe similarly configured.

Incidentally, the magnetic substance layer 112 may be selectively provided on only some of the probe pins, for example, only on the first and second probe pins 111_G and 111_D and not the third probe pins 111_S. The amplitude of noise at the gate G and the drain D may be greater than the amplitude of noise at the source S. Therefore, by selectively providing the magnetic substance layer 112 on only the first and second probe pins 111_G and 111_D, the occurrence of noise may be reliably reduced at lower cost than providing a magnetic substance layer 112 on all the probe pins.

Moreover, in some embodiments, the magnetic substance layer 112 may cover only some portion of the full length of the probe pins 111_G, 111_D, and 111_S. For example, the second end E2 portions (e.g., halves) of the probe pins 111_G, 111_D, and 111_S can be coated with the magnetic substance layer 112 and the first end portions (e.g., halves) of the probe pins 111_G, 111_D, and 111_S may be left uncoated by the magnetic substance layer 112. In general, the closer to the MOS transistor 2, the greater the amplitude of noise will be. Therefore, as a result of the magnetic substance layer 112 covering of the halves of each of the probe pins 111_G, 111_D, and 111_S closest to where the second end E2 is located, the occurrence of noise may still be sufficiently reduced.

In FIG. 3, the magnetic substance layer 112 has a uniform thickness. However, the magnetic substance layer 112 in the second portions 1112_G, 1112_D, and 1112_S maybe made thicker than the magnetic substance layer 112 in the first portions 1111_G, 1111_D, and 1111_S. That is, the magnetic substance layer 112 may be thicker in some portions than the magnetic substance layer 112 in some other portions. Portions of the probe pins 111_G, 111_D, and 111_S, the portions that significantly contribute to pressing of the second ends E2, are the first portions 1111_G, 1111_D, and 1111_S. The reason is as follows. Since the first portions 1111_G, 1111_D, and 1111_S extend in the direction D3 orthogonal to the pressing direction D2, the first portions 1111_G, 1111_D, and 1111_S may exert force by bending in the pressing direction D2 when the second ends E2 are made to strike the electrodes G, D, and S of the MOS transistor 2 from the pressing direction D2. Preferably, in such first portions 1111_G, 1111_D, and 1111_S, the thickness of the magnetic substance layer 112 is controlled in such a way that the elastic force is not impaired by the magnetic substance layer 112 being too thick. On the other hand, portions of the probe pins 111_G, 111_D, and 111_S, that significantly contribute to a reduction of the occurrence of noise, are the second portions 1112_G, 1112_D, and 1112_S because the distances between the second portions 1112_G, 1112_D, and 1112_S and the MOS transistor 2 in which noise is caused are short. Preferably, in such second portions 1112_G, 1112_D, and 1112_S, a sufficiently thick magnetic substance layer 112 is ensured in order to reduce the occurrence of noise. Therefore, by making the magnetic substance layer 112 in the second portions 1112_G, 1112_D, and 1112_S thicker than the magnetic substance layer 112 in the first portions 1111_G, 1111_D, and 1111_S, both the stability of contact of the probe pins 111_G, 111_D, and 111_S and the effect of reducing the occurrence of noise may be increased.

### Inspection Device 13

As depicted in FIG. 1, the inspection device 13 is electrically connected to the probe pins 111_G, 111_D, and 111_S via the electric wires 12. The inspection device 13 inputs an inspection signal to the electrodes G, D, and S of the MOS transistor 2 through the electric wires 12 and the probe pins 111_G, 111_D, and 111_S. The inspection signal is an electrical signal for inspecting the electrical characteristics of the MOS transistor 2 (the semiconductor device) . The inspection signal may be a current which is input to the electrodes G, D, and S of the MOS transistor 2 or a voltage which is input between the electrodes G, D, and S of the MOS transistor 2.

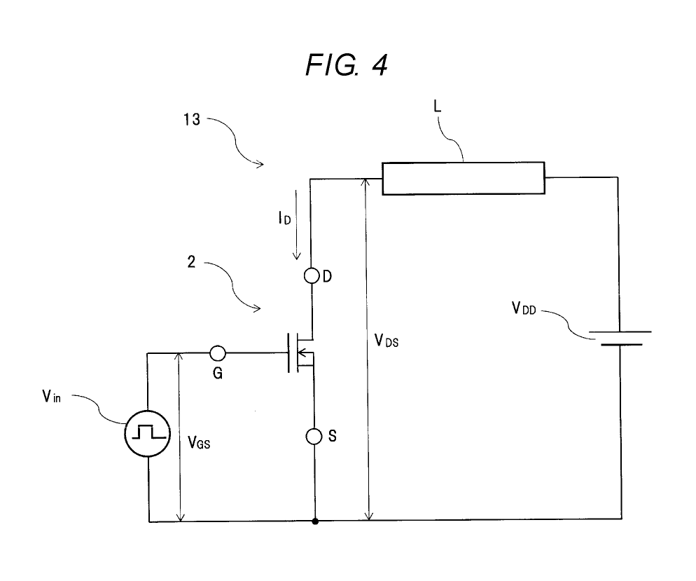

FIG. 4 is an equivalent circuit diagram depicting an example of the inspection device 13 of the semiconductor inspection apparatus 1 in FIG. 1. The inspection device 13 in FIG. 4 is an L load test circuit that conducts an L load test which is carried out on the MOS transistor 2. The L load test is a test of the resistance of the MOS transistor 2 to a voltage which is applied to the MOS transistor 2 from an L load when the L load (the inductive load) in which energy is accumulated is turned off. The L load test may also be referred to as a screening test or a breaking test.

As depicted in FIG. 4, the inspection device 13 includes a gate power supply Vᵢₙ, a drain power supply V_{DD} (a direct-current power supply), and a load inductance L. The gate power supply Vᵢₙ, is connected between the gate G and the source S of the MOS transistor 2 via the first and third probe pins 111_G and 111_S. The gate power supply Vᵢₙ inputs (applies) a gate voltage V_{GS} as the inspection signal to the MOS transistor 2. The drain power supply V_{DD} is connected between the drain D and the source S of the MOS transistor 2 via the second and third probe pins 111_D and 111_S. The drain power supply V_{DD} inputs a drain voltage V_{DS} as the inspection signal to the MOS transistor 2. The load inductance L has one end connected to the second probe pin 111_D (the drain D) and the other end connected to a positive electrode of the drain power supply V_{DD}. The load inductance L accumulates magnetic energy based on a drain current I_{D} when the MOS transistor 2 is turned on. The load inductance L applies a voltage based on the accumulated magnetic energy to the MOS transistor 2 when the MOS transistor 2 is turned off. Moreover, the inspection device 13 may include an oscilloscope that monitors the waveform of the inspection signal.

As depicted in FIG. 1, the ferrite core 14 is arranged on the electric wires 12. The ferrite core 14 is a core rod that is formed of magnetic material, for example, a ferrite material and is attached to the electric wires 12 so as to cover the electric wires 12 (which may be a cable in some embodiments) . The ferrite core 14 reduces noise by absorbing a magnetic field caused by a high-frequency noise current flowing through the electric wires 12 and converting the magnetic energy into heat. Here, the electric wires 12 pass through the ferrite core 14. Also, the electric wires 12 may be wound around the ferrite core 14 one or more times in order to increase the effect of suppressing noise.

As depicted in FIG. 2, the moving apparatus 15 is connected to the fixing member 113. In conjunction with the fixing member 113, the moving apparatus 15 moves the probe pins 111_G, 111_D, and 111_S in the pressing direction D2 (downward) or in a direction (upward) opposite to the pressing direction D2. The moving apparatus 15 may be provided with, for example, a motor and a conversion mechanism (for example, a rack and pinion gearing) that converts the rotational motion of the motor into a translational motion along the pressing direction D2. Various linear actuator mechanisms may be used in the moving apparatus 15 and the provided examples are not limitations.

### Semiconductor Inspection Method

Next, a semiconductor inspection method using the semiconductor inspection apparatus 1 will be described. The semiconductor inspection method described as an example is an inspection process in a process of producing a MOS transistor 2 (that is, a semiconductor production method). Here, the MOS transistor 2 is formed by various semiconductor production processes prior to the inspection process, which is used to confirm the success or failure of the various semiconductor production processes.

When the L load test is conducted by using the semiconductor inspection apparatus 1, the end faces EF2 of the probe pins 111_G, 111_D, and 111_S are brought into contact with the electrodes G, D, and S of the MOS transistor 2.

Here, the semiconductor inspection apparatus 1 may be placed somewhere on a conveyor line of an unillustrated conveying apparatus (for example, a conveyor belt) that automatically conveys the MOS transistor 2 in such a way that the semiconductor inspection apparatus 1 may get closer to or move away from (may move upward and downward) with respect to the conveyor line. In this case, the conveying apparatus may detect a state in which the MOS transistor 2 has been conveyed to a placement position (hereinafter also referred to as an inspection position) of the semiconductor inspection apparatus 1 based on a previously set distance by which the MOS transistor 2 is conveyed, the detection results obtained by various sensors, and so forth. The conveying apparatus may temporarily stop conveying the MOS transistor 2 when detected the MOS transistor 2 has been conveyed to the inspection position. Then, the moving apparatus 15 may move the probe pins 111_G, 111_D, and 111_S downward toward the MOS transistor 2 which is at rest on the conveyor line and thus bring the probe pins 111_G, 111_D, and 111_S into contact with the MOS transistor 2.

When the end faces EF2 make contact with the electrodes G, D, and S of the MOS transistor 2, the first portions 1111_G, 1111_D, and 1111_S of the probe pins 111_G, 111_D, and 111_S bend/flex in the pressing direction D2 when pressed by the moving apparatus 15. The elastic force in accordance with the bending of the first portions 1111_G, 1111_D, and 1111_S is transferred to the second portions 1112_G, 1112_D, and 1112_S from the first portions 1111_G, 1111_D, and 1111_S and is transferred to the electrodes G, D, and S of the MOS transistor 2 from the second portions 1112_G, 1112_D, and 1112_S. For example, the probe pins 111_G, 111_D, and 111_S apply a force in the pressing direction D2 that acts on the electrodes G, D, and S of the MOS transistor 2 with the fixing member 113 being used as a pivot. With this force, the end faces EF2 make contact with (are pressed against) the electrodes G, D, and S of the MOS transistor 2 with stability.

Next, the inspection device 13 inputs the gate voltage V_{GS} and the drain voltage _{DS} to the MOS transistor 2 from the probe pins 111_G, 111_D, and 111_S via the end faces EF2.

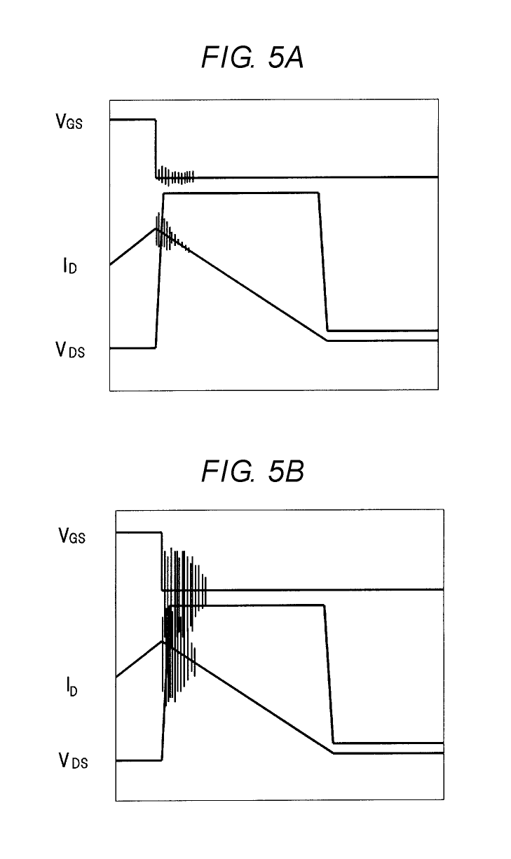

FIG. 5A is a schematic waveform diagram obtained in the L load test using probe 11 formed according to the first embodiment. FIG. 5B is a schematic waveform diagram obtained by the L load test using a probe of a comparative example. The probe of the comparative example corresponds to a probe obtained by removing the magnetic substance layer 112 from the probe 11 formed according to the first embodiment.

Here, in the L load test, the MOS transistor 2 is turned on and turned off by the gate voltage V_{GS}. At this time, a series resonant circuit is formed between lead inductances L_{G}, L_{D}, and Lₛ of the electrodes G, D, and S (lead wires/terminals) of the MOS transistor 2 and parasitic capacitances C_{GD}, C_{DS}, and C_{GS} of the MOS transistor 2. As a result of the formation of the resonant circuit, an oscillation or noise phenomenon may occur in the gate voltage V_{GS} and the drain voltage V_{DS}.

When only the ferrite core 14 is provided, as in the comparative example depicted in FIG. 5B, the amplitude of noise of the gate voltage V_{GS} and the drain voltage V_{DS} cannot be sufficiently reduced when the MOS transistor 2 is turned off by the gate voltage V_{GS}. The reason is as follows. Although the amplitude of noise is large near the MOS transistor 2 in which the resonant circuit is formed, the ferrite core 14 cannot contribute to a reduction of this noise because the ferrite core 14 is located well away from the MOS transistor 2.

On the other hand, the semiconductor inspection apparatus 1 includes the magnetic substance layer 112 on the probe pins 111_G, 111_D, and 111_S close to the MOS transistor 2. The magnetic substance layer 112 may thus absorb this noise having a large amplitude generated near the MOS transistor 2 and convert this noise into heat or otherwise disperse. As a result, as depicted in FIG. 5A, the amplitude of noise of the gate voltage V_{GS} and the drain voltage V_{DS} may be sufficiently reduced by inclusion of magnetic substances layer 112.

Therefore, the destruction of the MOS transistor 2 which might result from the large amplitude noise maybe suppressed. As a result, the manufacturing yield of the MOS transistor 2 devices may be increased. Moreover, false or faulty inspection results may also be reduced.

The results obtained by conducting the L load test on 40 MOS transistors 2 using the semiconductor inspection apparatus 1 according to the first embodiment revealed that as many as 36 of the 40 MOS transistors 2 to be non-defective items and no more than 4 of the 40 MOS transistors 2 were determined to be defective items. On the other hand, when a L load test on the 36 MOS transistors 2 determined to be non-defective by the initial testing using the semiconductor inspection apparatus 1 was performed using the semiconductor inspection apparatus according to the comparative example, the L load test found 5 of the 36 MOS transistors 2 were determined to be defective. The above results show that the semiconductor inspection apparatus 1 according to the first embodiment reduces the occurrence of noise with a large amplitude and reduce the occurrence of destruction of the MOS transistor 2 and improves reliability of inspection results.

### Method for Producing the Semiconductor Inspection Apparatus 1

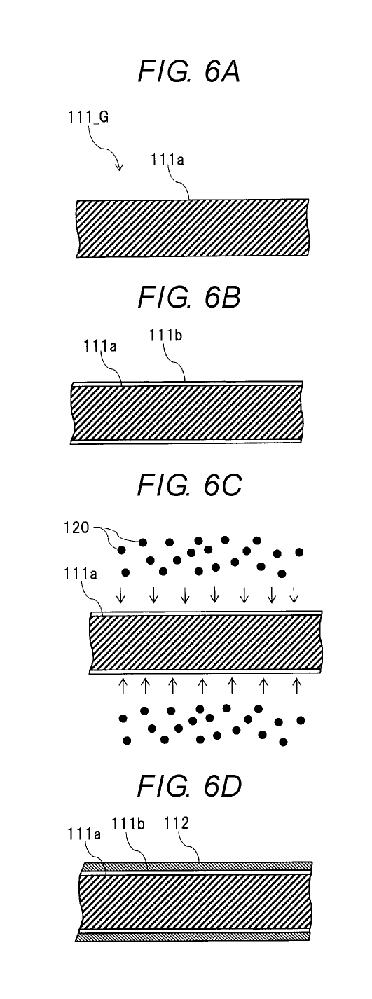

Next, a method for producing the semiconductor inspection apparatus 1 will be described. Incidentally, the method for producing the semiconductor inspection apparatus 1 includes a method for producing a probe. FIG. 6A is a cross sectional view of the probe pin 111_G depicting a process of forming the probe pin 111_G. FIG. 6B is a cross sectional view depicting a process of forming a primary coating on the probe pin 111_G. FIG. 6C is a cross sectional view depicting a process of magnetic substance thermal spraying on the probe pin 111_G. Thermal spraying is a surface treatment method that forms a film on the surface of an object by spraying, particles sprayed on to the surface are melted or are otherwise formed into a continuous coating by being heated. FIG. 6D is a cross sectional view depicting a process of hardening the magnetic substance after the thermal spraying process. Incidentally, only the first probe pin 111_G is depicted in FIGS. 6A to 6D as a representative example, but the second and third probe pins 111_D and 111_S can be provided in a manner similar to the first probe pin 111_G in FIGS. 6A to 6D.

First, as depicted in FIG. 6A, the probe pin 111_G is formed. The probe pin 111_G may be formed of, for example, a conductive material such as tungsten, bainite steel, or beryllium copper (BeCu). A molding process may be used in the formation of the probe pin 111_G in some embodiments.

Next, as depicted in FIG. 6B, primary coating for magnetic substance thermal spraying is performed on the outer periphery 111a of the probe pin 111_G. Incidentally, in FIG. 6B, this primary coating is depicted as a primary coating layer 111b. The primary coating layer 111b is not specifically depicted in FIG. 3. The primary coating is performed on the probe pin 111_G around the entire perimeter thereof in at least part of an area of the probe pin 111_G in the arrangement direction D1. Moreover, primary coating layer 111b may be, for example, blasting layer (surface roughened layer) or a nickel plating.

Then, as depicted in FIG. 6C, thermal spraying of a magnetic substance 120 is performed on the probe pin 111_G (the outer periphery 111a) having the primary coating layer 111b formed thereon. At this time, though not specifically depicted in the drawing, thermal spraying of the magnetic substance 120 can also be performed on the second end E2 portion of the probe pin. Incidentally, some portion of the second end E2 or specifically the end face EF2 may be masked such that thermal spraying of the magnetic substance 120 is not performed on the masked portions. Or as previously discussed, the thermal spraying process can be conducted in a manner to provide different layer thicknesses on different portions of the probe pin. Similarly, some portions of the probe pin may be intentionally left uncoated by the thermal spraying process.

The magnetic substance 120 may be a ferrite, a ceramic whose main ingredient is an iron oxide. For example, the ferrite may be a spinel ferrite AFe₂O₄ (where A is a metal such as Mn, Co, Ni, Cu, Zn, or the like) having a Spinel crystal structure. Moreover, the ferrite may be hexagonal ferrite AFe₁₂O₁₉ (where A is a metal such as Ba, Sr, Pb, or the like) having a hexagonal crystal structure. Furthermore, the ferrite may be garnet ferrite RFe₅O₁₂ (where R is a rare-earth element such as a lanthanide, scandium, or yttrium) having a garnet crystal structure. A method of thermal spraying is also not limited to any particular method, for example, the method of thermal spraying may be powder frame thermal spraying in which a powdered magnetic substance is used as a thermal spraying material.

Next, as depicted in FIG. 6D, the thermal sprayed magnetic substance 120 is cooled and hardened, whereby the magnetic substance layer 112 is formed. Cooling may be performed, for example, by heat exchange between the magnetic substance 120 and the outside air.

Then, the magnetic substance layer 112 on the second end E2 may ground by a file or other processing, whereby the tip face 112a of the magnetic substance layer 112 is retreated or angled toward the first end E1 from around the perimeter of the second end E2, is formed (see FIG. 3). The formation of the end face 112a of the magnetic substance layer 112 may also be called chamfering process. Then, one end of the electric wire 12 is connected to the end face EF1 of the first end E1. Moreover, the other end of the electric wire 12 is connected to the inspection device 13.

When a noise absorption sheet is attached to a probe pin to reduce the occurrence of noise, limitations are imposed on a position and an area in which the noise absorption sheet can be attached according to the shape of the probe pin. For example, although the noise absorption sheet could be attached to the upper and lower faces of the probe pins 111_G, 111_D, and 111_S over a relatively large area, the noise absorption sheet cannot be easily attached to all the side faces of these probe pins 111_G, 111_D, and 111_S. In addition, as a result of limitations being imposed on a position and an area in which the noise absorption sheet is attached, a reduction of the occurrence of noise is not easily performed. Moreover, when the noise absorption sheet is attached before the probe prior to use, the noise absorption sheet may peel off because the working stress (e.g., flexure of probe pins during the inspection process) causes the noise absorption sheet to detach at flex points. Thus, limitations would have to be imposed on the shape of the probe pin to allow the noise absorption sheet to be attached and to prevent the noise absorption sheet from peeling off during operation.

On the other hand, in the first embodiment, the magnetic substance layer 112 is formed by performing thermal spraying of the magnetic substance 120. As a result of thermal spraying of the magnetic substance 120, the magnetic substance layer 112 may be formed in a desired position and area irrespective of the shapes of the probe pins 111_G, 111_D, and 111_S. Moreover, since the adhesion between the magnetic substance layer 112 and the probe pins 111_G, 111_D, and 111_S is high, the probe pins 111_G, 111_D, and 111_S maybe worked on (ground by a file, for example) after thermal spraying of the magnetic substance 120. Therefore, according to the first embodiment, the flexibility of the design of the probe pins 111_G, 111_D, and 111_S may be increased with the occurrence of noise being reduced.

As described above, according to the first embodiment, the occurrence of noise maybe reduced by providing the magnetic substance layer 112. As a result, the destruction of the MOS transistor 2 during inspection may be suppressed and the manufacturing yield may be increased. Moreover, since the magnetic substance layer 112 is formed by thermal spraying, the flexibility of the design of the probe pins 111_G, 111_D, and 111_S may be increased. Furthermore, the end faces EF2 may be brought into contact with the electrodes G, D, and S of the MOS transistor 2 with stability by the probe pins 111_G, 111_D, and 111_S having elasticity, the probe pins 111_G, 111_D, and 111_S bent in the pressing direction D2 on the side where the second ends E2 are located. By bringing the end faces EF2 into contact with the electrodes G, D, and S of the MOS transistor 2 with stability, the MOS transistor 2 may be inspected in an appropriate manner.

### Second Embodiment

Next, as a second embodiment, an embodiment in which the probe pin is a coil spring-type (helical spring) probe pin will be described. Incidentally, in the description of the second embodiment, the component sections that have counterparts thereof in the first embodiment are identified with the same reference numerals and overlapping explanations has been omitted.

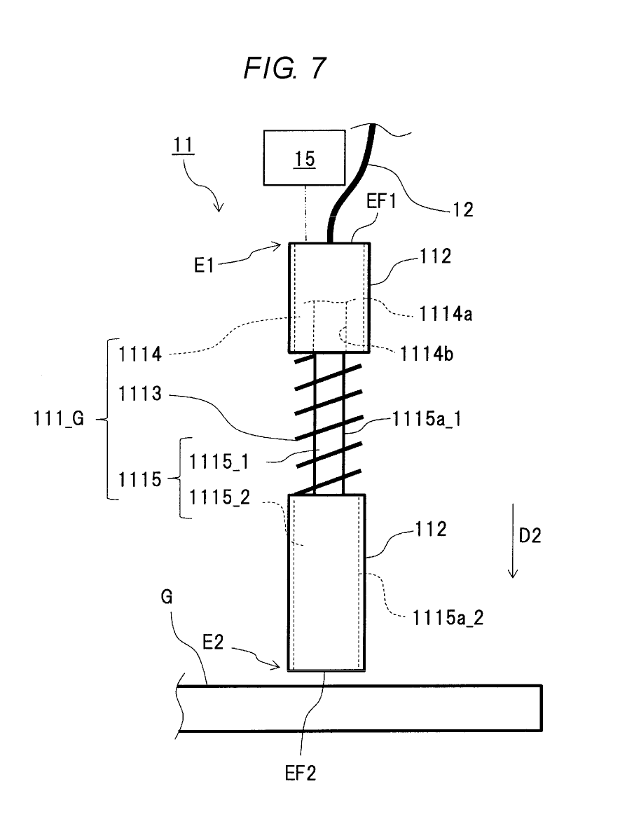

FIG. 7 is a front view of a probe 11 according to the second embodiment. Incidentally, in FIG. 7, although a front view of a first probe pin 111_G is depicted as a representative example, front views of second and third probe pins 111_D and 111_S are the same as the front view of FIG. 7.

A semiconductor inspection apparatus 1 according to the second embodiment differs from the semiconductor inspection apparatus 1 according to the first embodiment in that the probe pin 111_G of the probe 11 is the coil spring-type probe pin 111_G. More specifically, as depicted in FIG. 7, the probe pin 111_G includes a coil spring 1113, a main body section 1114, and a movable section 1115.

The coil spring 1113 extends along the pressing direction D2. More specifically, the coil spring 1113 is a compression spring that exerts an elastic force (a restoring force) in the pressing direction D2.

The main body section 1114 is a component section that holds (attaches) the coil spring 1113 and the movable section 1115. The main body section 1114 includes a first end E1. Moreover, as depicted in FIG. 7, the main body section 1114 is connected to one end (an end on the side where the first end E1 is located) of the coil spring 1113. More specifically, the main body section 1114 has a cylindrical outer periphery 1114a extending from the end face EF1 to the one end of the coil spring 1113. In addition, the one end of the coil spring 1113 is connected to a tip face of the main body section 1114 on the side where a second end E2 is located. At the radial center of the main body section 1114, a hole 1114b into which a first movable section 1115_1 of the movable section 1115 is inserted is formed.

The movable section 1115 is a component section that may be moved by an external force or the force generated by the coil spring 1113. The movable section 1115 includes the second end E2. Moreover, the movable section 1115 is connected to the other end (an end on the side where the second end E2 is located) of the coil spring 1113. More specifically, the movable section 1115 includes the first movable section 1115_1 and a second movable section 1115_2. The first movable section 1115_1 is surrounded with the coil spring 1113. The first movable section 1115_1 has an outer periphery 1115a_1 whose outside diameter is smaller than the winding diameter of the coil spring 1113. A predetermined area of the first movable section 1115_1 on the side where the first end E1 is located is inserted into the main body section 1114 through the hole 1114b. The second movable section 1115_2 connects to the first movable section 1115_1 at an end of the first movable section 1115_1 on the side where the second end E2 is located. The second movable section 1115_2 has an outer periphery 1115a_2 whose diameter is larger than the diameter of the first movable section 1115_1.

Then, in the second embodiment, the magnetic substance layer 112 covers the main body section 1114 and the second movable section 1115_2 of the movable section 1115. That is, in the second embodiment, at least part of an area of the probe pin 111_G between the first end E1 and the second end E2, the area in which the magnetic substance layer 112 is provided, is the main body section 1114 and the second movable section 1115_2. On the other hand, the magnetic substance layer 112 does not cover the first movable section 1115_1 of the movable section 1115. That is, the outer periphery 1115a_1 of the first movable section 1115_1 is exposed to the outside.

The magnetic substance layer 112 according to the second embodiment may be formed by thermal spraying of the magnetic substance 120 performed on the probe pin 111_G in a state in which, for example, the first movable section 1115_1, the coil spring 1113, and the second end E2 are masked. A specific form of the mask is not limited to a particular form. For example, a metal or a heat-resistant tape whose heatproof temperature is higher than the temperature of the magnetic substance 120 in a molten state may be used as a masking material.

In the semiconductor inspection apparatus 1 according to the second embodiment having the above-described configuration, the moving apparatus 15 moves the probe pins 111_G, 111_D, and 111_S in the pressing direction D2. The probe pins 111_G, 111_D, and 111_S moved in the pressing direction D2 make contact with the electrodes G, D, and S of the MOS transistor 2 at the end faces EF2 of the movable sections 1115. The movable sections 1115 of the probe pins 111_G, 111_D, and 111_S make contact with the electrodes G, D, and S, which hinders the movable sections 1115 of the probe pins 111_G, 111_D, and 111_S from moving in the pressing direction D2. On the other hand, the main body sections 1114 of the probe pins 111_G, 111_D, and 111_S are connected to the elastically deformable coil springs 1113 and may vary the amount of insertion of the first movable sections 1115_1 in the holes 1114b. As a result, the main body sections 1114 move in the pressing direction D2 while compressing the coil springs 1113 even after the movable sections 1115 stop as a result of making contact with the electrodes G, D, and S. At this time, the first movable sections 1115_1 slide relative to the coil springs 1113 which are compressed. The compressed coil springs 1113 make a force corresponding to the compression act on the movable sections 1115. As a result, the end faces EF2 stably make contact with the electrodes G, D, and S of the MOS transistor 2. Then, in a state in which the end faces EF2 stably make contact with the electrodes G, D, and S, the inspection signal may be appropriately applied to the MOS transistor 2 from the probe pins 111_G, 111_D, and 111_S and the L load test may be conducted in an appropriate manner.

When the magnetic substance layer 112 is formed on the first movable sections 1115_1, when the first movable sections 1115_1 slide with respect to the coil springs 1113, there is a possibility that dust particles of the magnetic substance 120 are generated as a result of the first movable sections 1115_1 being rubbed with the coil springs 1113. The dust particles of the magnetic substance 120 fall onto the electrodes G, D, and S of the MOS transistor 2 and contaminate the MOS transistor 2. On the other hand, in the second embodiment, since the magnetic substance layer 112 is formed in an area other than the first movable sections 1115_1, the generation of the dust particles of the magnetic substance 120 may be avoided.

As described above, according to the second embodiment, since the end faces EF2 maybe stably brought into contact with the electrodes G, D, and S of the MOS transistor 2 by the probe pins 111_G, 111_D, and 111_S provided with the coil springs 1113, the MOS transistor 2 may be inspected in an appropriate manner. Moreover, as is the case with the first embodiment, since the occurrence of noise may be reduced by the magnetic substance layer 112, the destruction of the MOS transistor 2 may be suppressed. Furthermore, by avoiding the generation of the dust particles of the magnetic substance 120, quality degradation of the MOS transistor 2 may be prevented.

### Third Embodiment

Next, as a third embodiment, an embodiment in which insulators are provided between the probe pins will be described. Incidentally, in the description of the third embodiment, the component sections that have counterparts thereof in the first embodiment are identified with the same reference numerals and overlapping explanations are omitted.

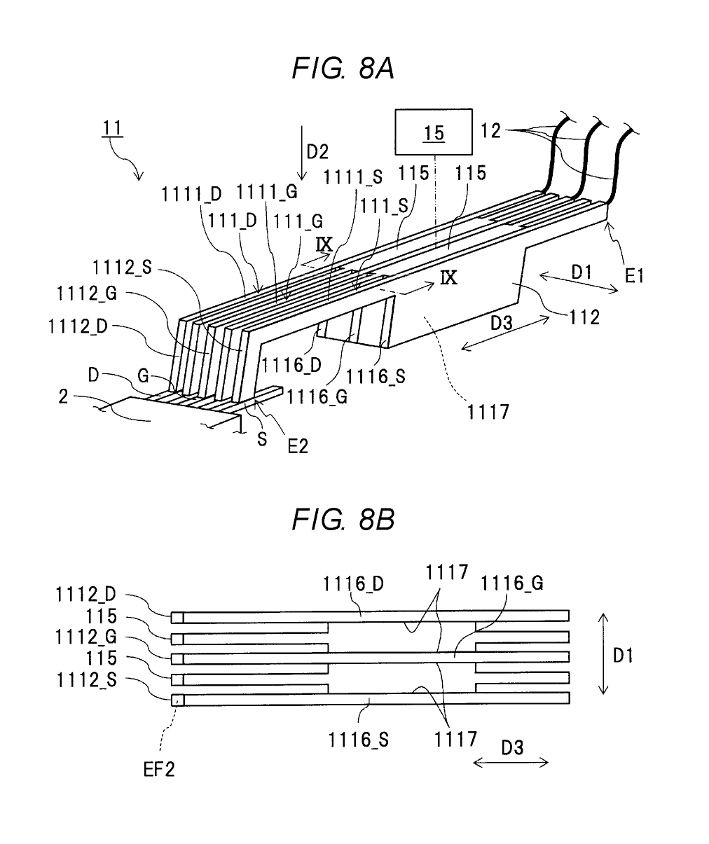

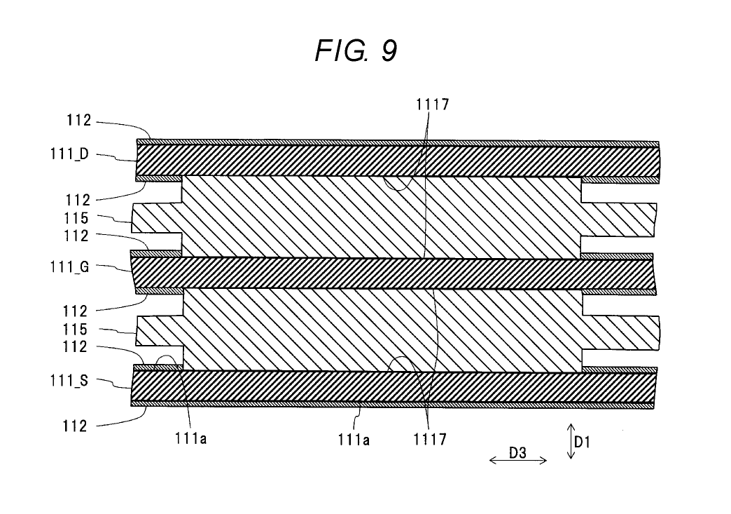

FIG. 8A is a perspective view of a probe 11 according to the third embodiment. FIG. 8B is a plan view of FIG. 8A. FIG. 9 is a sectional view taken on the line IX-IX of FIG. 8A. Incidentally, in FIG. 9, the primary coating layer 111b (see FIGS. 6A to 6D) is not specifically depicted, but may be present.

As depicted in FIG. 8A, probe pins 111_G, 111_D, and 111_S of the third embodiment have first portions 1111_G, 1111_D, and 1111_S and second portions 1112_G, 1112_D, and 1112_S and has elasticity.

On the other hand, the space left between the probe pins 111_G, 111_D, and 111_S according to the third embodiment and the width of each of the probe pins 111_G, 111_D, and 111_S according to the third embodiment (the size of each of the probe pins 111_G, 111_D, and 111_S in the direction D1) are generally smaller than the space left between the probe pins 111_G, 111_D, and 111_S according to the first embodiment. That is, the spacing between the probe pins 111_G, 111_D, and 111_S according to the third embodiment is smaller than the spacing between the probe pins 111_G, 111_D, and 111_S according to the first embodiment and the probe pins 111_G, 111_D, and 111_S according to the third embodiment are finer (narrower in width) than the probe pins 111_G, 111_D, and 111_S according to the first embodiment. A semiconductor inspection apparatus 1 according to the third embodiment provided with such probe pins 111_G, 111_D, and 111_S may inspect a finer-pitch (electrode/terminal spacing is narrower) MOS transistor 2 as compared to the first embodiment.

Moreover, the probe pins 111_G, 111_D, and 111_S according to the third embodiment differ from the probe pins 111_G, 111_D, and 111_S according to the first embodiment in that the probe pins 111_G, 111_D, and 111_S according to the third embodiment include connecting sections 1116_G, 1116_D, and 1116_S. The connecting sections 1116_G, 1116_D, and 1116_S correspond to components obtained by extending areas of the first portions 1111_G, 1111_D, and 1111_S located at the center in a longitudinal direction (the D3 direction of FIGS. 8A and 8B), in the pressing direction D2. The connecting sections 1116_G, 1116_D, and 1116_S define the connecting locations of insulators 115.

Moreover, the probe 11 according to the third embodiment differs from the probe 11 according to the first embodiment in that the insulators 115 are provided between the probe pins 111_G, 111_D, and 111_S. The insulators 115 are connected to connecting faces 1117 of the probe pins 111_G, 111_D, and 111_S between the probe pins 111_G, 111_D, and 111_S adjacent to each other in the arrangement direction D1. The connecting faces 1117 are the side faces of the above-described connecting sections 1116_G, 1116_D, and 1116_S. The insulators 115 and the connecting sections 1116_G, 1116_D, and 1116_S are secured with screws, for example, and the side faces of the insulators 115 and the connecting faces 1117 of the connecting sections 1116_G, 1116_D, and 1116_S are contacting one another.

On the other hand, as depicted in FIG. 8B, the insulators 115 are not in contact with the probe pins 111_G, 111_D, and 111_S in locations other than the locations in which the connecting sections 1116_G, 1116_D, and 1116_S exist because the width of each insulator 115 (the size of each insulator 115 in the arrangement direction D1) is thick in the locations in which the connecting sections 1116_G, 1116_D, and 1116_S exist and is thin in locations other than the locations in which the connecting sections 1116_G, 1116_D, and 1116_S exist.

In addition, in the third embodiment, as depicted in FIG. 9, the magnetic substance layer 112 covers the probe pins 111_G, 111_D, and 111_S other than on the connecting faces 1117. That is, in the third embodiment, at least portion of an area of each of the probe pins 111_G, 111_D, and 111_S between the first end E1 and the second end E2, the area in which the magnetic substance layer 112 is provided, is a portion other than the portions in which the insulators 115 contacting the probe pins.

As is the case with the second embodiment, the magnetic substance layer 112 according to the third embodiment may be formed by thermal spraying of the magnetic substance 120 performed on the probe pins 111_G, 111_D, and 111_S in a state in which the connecting faces 1117 are masked.

Since the probe pins 111_G, 111_D, and 111_S are narrowly spaced, the semiconductor inspection apparatus 1 according to the third embodiment with the above-described configuration may bring the end faces EF2 into contact with the electrodes G, D, and S of a fine-pitch MOS transistor 2. In so doing, the elasticity of the probe pins 111_G, 111_D, and 111_S allows the end faces EF2 to be brought into contact with the electrodes G, D, and S of the MOS transistor 2 with stability.

In addition, by applying the inspection signal to the MOS transistor 2 from the probe pins 111_G, 111_D, and 111_S, the L load test of the fine-pitch MOS transistor 2 may be conducted. The insulators 115 are provided between the probe pins 111_G, 111_D, and 111_S so even when the probe pins 111_G, 111_D, and 111_S are narrowly spaced, a short circuiting does not occur between the probe pins 111_G, 111_D, and 111_S.

When the magnetic substance layer 112 is formed also on the connecting faces 1117, the thickness of the magnetic substance layer 112 reduces the assembly accuracy (the dimension accuracy in the arrangement direction D1) of the probe pins 111_G, 111_D, and 111_S. As a result of a reduction in the assembly accuracy, the space left between the arranged probe pins 111_G, 111_D, and 111_S cannot be easily made to be the same as the space left between the arranged electrodes G, D, and S of the MOS transistor 2. On the other hand, in the third embodiment, the magnetic substance layer 112 is formed on the outside of the connecting faces 1117. As a result, the assembly accuracy may be prevented from being reduced due to the thickness of the magnetic substance layer 112 and the space left between the arranged probe pins 111_G, 111_D, and 111_S may be made to be the same as the space left between the arranged electrodes G, D, and S of the MOS transistor 2. As a result, the end faces EF2 may be brought into contact with the electrodes of a fine-pitch MOS transistor 2 with reliability.

Moreover, a noise absorption sheet cannot easily be attached to the fine probe pins 111_G, 111_D, and 111_S according to the third embodiment. In the third embodiment, however, by performing thermal spraying of the magnetic substance 120, the magnetic substance layer 112 maybe reliably formed on the fine probe pins 111_G, 111_D, and 111_S. As a result, the occurrence of noise may be reduced even when a fine-pitch MOS transistor 2 is inspected.

Moreover, when the probe pins 111_G, 111_D, and 111_S are fine as in the third embodiment, thermal spraying of the magnetic substance 120 is not easily performed with the second ends E2 being masked. However, as described earlier, by grinding the magnetic substance layer 112 on the second ends E2 after thermal spraying of the magnetic substance 120, the end faces EF2 of the second ends E2 of the fine probe pins 111_G, 111_D, and 111_S of this third embodiment may be exposed to the outside easily and reliably.

As described above, according to the third embodiment, with the fine probe pins 111_G, 111_D, and 111_S with a small spacing therebetween, the probe pins 111_G, 111_D, and 111_S which are insulated by the insulators 115, the end faces EF2 may be brought into contact with the electrodes G, D, and S of the fine-pitch MOS transistor 2 with reliability and stability. As a result, the fine-pitch MOS transistor 2 may be appropriately inspected. Moreover, as is the case in the first embodiment, since the occurrence of noise maybe reduced by the magnetic substance layer 112, the destruction of the MOS transistor 2 may be suppressed and the manufacturing yield may be increased.

The example embodiments may also be applied to inspect electrical characteristics other than by a L load test-type. Moreover, in order to absorb efficiently noise in a necessary frequency band, the magnetic properties of a magnetic substance material (the magnetic substance layer 112) may be selected in accordance with an expected oscillation frequency.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein maybe made without departing from the spirit of the inventions. The accompanying claims and their equivalents are intended to cover such forms or modifications as would fall within the scope and spirit of the inventions.

What is claimed is:

1. A probe, comprising:
a first probe pin having a first end and a second end, the first end being connectable to a semiconductor inspection apparatus and the second end for contacting a first electrode of a semiconductor device, wherein
the first probe pin has at least a portion between the first and second ends that is provided with a magnetic substance layer.

2. The probe according to claim 1, wherein
the first probe pin is configured to apply a force for maintaining contact between the second end and the first electrode when placed in contact with the first electrode, and
the magnetic substance layer on the first probe pin includes a portion which is flush with an end face on the second end of the first probe pin.

3. The probe according to claim 1, wherein
the first probe pin comprises a first portion extending from the first end in a first plane and a second portion extending from the second end in a second plane that crosses the first plane, and
the first probe pin is configured to apply a force for maintaining contact between the second end and the first electrode by having at least one the first and second portions flex out of the respective first or second plane when the second end is pressed against the first electrode.

4. The probe according to claim 1, wherein the first probe pin includes:
a coil spring;
a main body section that includes the first end and is connected to a first end of the coil spring; and
a movable section that includes the second end and is connected to a second end of the coil spring, the movable section including:
a first movable section including a portion surrounded by the coil spring; and
a second movable section connected the portion of the first movable section outside the coil spring, the second movable section including an end face of the second end of the first probe pin, wherein
the coil spring is configured to apply a force for maintaining contact between the second end and the first electrode when the second end is pressed against the first electrode.

5. The probe according to claim 1, further comprising:
a second probe pin having a first end and a second end, the first end being connectable to the semiconductor inspection apparatus and the second end for contacting a second electrode of the semiconductor device;
an insulator between the first and second probe pins, the insulator contacting only a portion of each of the first and second probe pins, wherein
the second probe pin has at least a portion between the first and second ends that is coated with the magnetic substance layer,
the second probe pin is configured to apply a force for maintaining contact between the second end of the second probe pin and the second electrode when placed in contact with the second electrode, and
the first and second probe pins are spaced from each other at a distance corresponding to a spacing between the first and second electrodes.

6. The probe according to claim 1, wherein a thickness of the magnetic substance layer is different along a longitudinal direction of the first probe pin.

7. The probe according to claim 1, wherein the magnetic substance layer comprises a ferrite.

8. The probe according to claim 1, wherein the magnetic substance layer comprises one of a spinel ferrite of formula AFe₂O₄, a hexagonal ferrite of formula BFe₁₂O₁₉, and garnet ferrite of formula RFe₅O₁₂, wherein A represents a metal selected from one of manganese (Mn) , cobalt (Co) , nickel (Ni), copper (Cu) , and zinc (Zn) , B represents a metal selected from one of barium (Ba), strontium (Sr), and lead (Pb), and R represents a rare-earth element.

9. The probe according to claim 1, wherein the magnetic substance layer is formed by thermal spraying of a powdered magnetic substance.

10. The probe according to claim 1, wherein an end face of the second end is formed by a grinding process which removes a portion of the magnetic substance layer disposed on the second end of the first probe pin.

11. The probe according to claim 1, wherein
the first probe pin comprises a first portion extending from the first end in a first plane and a second portion extending from the second end in a second plane that crosses the first plane,
the first probe pin is configured to apply a force for maintaining contact between the second end and the first electrode by having at least one the first and second portions flex out of the respective first or second plane when the second end is pressed against the first electrode, and
the magnetic substance layer is formed by thermal spraying of a powdered magnetic substance and comprises one of a spinel ferrite of formula AFe₂O₄, a hexagonal ferrite of formula BFe₁₂O₁₉, and garnet ferrite of formula RFe₅O₁₂, wherein A represents a metal selected from one of manganese (Mn) , cobalt (Co), nickel (Ni), copper (Cu), and zinc (Zn), B represents a metal selected from one of barium (Ba), strontium (Sr), and lead (Pb), and R represents a rare-earth element.

12. A semiconductor inspection apparatus, comprising:
the probe according to claim 1; and
an inspection apparatus electrically connected to the first end of the first probe pin.

13. The semiconductor inspection apparatus according to claim 12, wherein
the probe further comprises second and third probe pins, and
a spacing between adjacent ones of the first, second, and third probe pins corresponds to a spacing of external terminals of a transistor device.

14. A method, comprising:
forming a magnetic substance layer on at least one portion of a probe pin of a probe for an inspection apparatus by performing thermal spraying of a magnetic substance on the probe pin, the at least one portion of the probe pin being between a first end and a second end of the probe pin, the first end being connectable to the inspection apparatus and the second end for making contact with an electrode of a semiconductor device, the probe pin configured to apply a force for maintaining contact between the second end and the electrode when placed in contact with the electrode.

15. The method of claim 14, further comprising:
electrically connecting the first end of the probe pin to the inspection apparatus.

16. A method, comprising:
contacting a probe to a semiconductor device, the probe comprising a first probe pin having a first end and a second end, the first end being connected to a semiconductor inspection apparatus and the second end contacting a first electrode of the semiconductor device, wherein the first probe pin has at least a portion between the first and second ends that is coated with a magnetic substance layer, and the first probe pin is configured to apply a force for maintaining contact between the second end and the first electrode; and
inputting an inspection signal to the semiconductor device via the first probe pin when the second end of the probe pin is contacting the first electrode.

17. The method of claim 16, wherein the magnetic substance layer on the first probe pin includes a portion which is flush with an end face on the second end of the first probe pin.

18. The method of claim 16, wherein
the first probe pin comprises a first portion extending from the first end in a first plane and a second portion extending from the second end in a second plane that crosses the first plane, and
the force for maintaining contact between the second end and the first electrode is generated when at least one the first and second portions flexes out of the respective first or second plane when the second end is pressed against the first electrode.

19. The method of claim 16, wherein the first probe pin includes:
a coil spring;
a main body section that includes the first end and is connected to a first end of the coil spring; and
a movable section that includes the second end and is connected to a second end of the coil spring, the movable section including:
a first movable section including a portion surrounded by the coil spring; and
a second movable section connected the portion of the first movable section outside the coil spring, the second movable section including an end face of the second end of the first probe pin, wherein
the force for maintaining contact between the second end and the first electrode is generated by compression of the coil spring when the second end is pressed against the first electrode.

20. The method of claim 16, wherein the probe further comprises:
a second probe pin having a first end and a second end, the first end connected to the semiconductor inspection apparatus and the second end for contacting with a second electrode of the semiconductor device; and
an insulator between the first and second probe pins, the insulator contacting only a portion of each of the first and second probe pins, wherein
the second probe pin has at least a portion between the first and second ends that is coated with the magnetic substance layer, and
the second probe pin is configured to apply a force for maintaining contact between the second end of the second probe pin and the second electrode when placed in contact with the second electrode;
the method further comprising:
fabricating the semiconductor device such that a spacing between the first and second electrodes corresponds to a spacing between the first and second probe pins.
